(19) United States
(12) Patent Application Publication
(10) Pub. No.: US 2026/0279667 A1
(43) Pub. Date: Sep. 17, 2026

(54) MATHOD FOR MANUFACTURING MULTILAYER CERAMIC SUBSTRATE HAVING GLASS LAYER AND MULTILAYER CERAMIC SUBSTRATE HAVING GLASS LAYER MANUFACTURED THEREOF

(71) Applicant: DIT CO.,LTD., Osan-si (KR)

(72) Inventor: Tae Hyung NOH, Siheung-si (KR)

(73) Assignee: DIT CO.,LTD., Osan-si (KR)

(21) Appl. No.: 19/319,750

(22) Filed: Sep. 5, 2025

(30) Foreign Application Priority Data
Feb. 19, 2025 (KR) 10-2025-0021587

(51) Int. Cl. H01G 4/008; H01G 4/30

(52) U.S. Cl. CPC H01G 4/0085; H01G 4/30

(57) ABSTRACT

The present invention relates to a method of manufacturing a multilayer ceramic substrate having a glass layer, which includes a preparing operation of preparing a plurality of ceramic sheets formed by sintering a ceramic green sheet, a via hole forming operation of forming via holes in the plurality of ceramic sheets, a via electrode forming operation of forming via electrodes in the via holes, a pattern electrode forming operation of forming a pattern electrode on one surface of each of the ceramic sheets, a bonding layer forming operation of applying a bonding agent onto one surface of each of the ceramic sheets to form a bonding layer, a bonding operation of manufacturing a multilayer ceramic substrate by bonding the plurality of the ceramic sheets to each other through the bonding layer, and a glass layer forming operation of forming a glass layer on one side of the manufactured multilayer ceramic substrate to implement a fine line width.

According to the present invention, there is an effect that a fine line width/spacing of 5 μm or less can be implemented on a surface of a multilayer ceramic substrate for an interposer through a mirrored glass layer.

### CROSS-REFERENCE TO RELATED APPLICATION

This application claims priority to and the benefit of Korean Patent Application No. 2025-0021587, filed on Feb. 19, 2025, the disclosure of which is incorporated herein by reference in its entirety.

### BACKGROUND

### 1. Field of the Invention

The present invention relates to a method of manufacturing a multilayer ceramic substrate having a glass layer and a multilayer ceramic substrate having the glass layer manufactured thereby, and more particularly, to a method of manufacturing a multilayer ceramic substrate having a glass layer by forming the glass layer for implementing a fine line width on one surface of a multilayer ceramic substrate for an interposer manufactured by bonding a plurality of pre-sintered ceramic sheets, and a multilayer ceramic substrate having the glass layer manufactured thereby.

### 2. Discussion of Related Art

Multilayer ceramic substrates are widely used as replacements for existing printed circuit boards (PCBs) due to their heat resistance, wear resistance, and excellent electrical characteristics, and their demand is gradually increasing. Multilayer ceramic substrates are used as composite components that combine active components such as semiconductor integrated circuit (IC) chips and passive components such as capacitors, inductors, and resistors or used as simple semiconductor IC packages. More specifically, multilayer ceramic substrates are widely used to constitute various electronic components such as power amplifier (PA) module substrates, radio frequency (RF) diode switches, filters, chip antennas, various package components, and composite devices.

A multilayer ceramic substrate includes a plurality of stacked ceramic layers, and various types of line conductors are formed in the multilayer ceramic substrate. Examples of the line conductors include a pattern electrode formed in a certain pattern and extending along a specific interface between ceramic layers, a via electrode formed to extend and pass through a specific ceramic layer, and an external electrode formed to extend onto an outer surface of the multilayer ceramic substrate. In order to increase the multilayer ceramic substrate's functionality, density, and performance, it is essential to arrange the above-described line conductors at a high density.

Such multilayer ceramic substrates are generally manufactured by a method referred to as a green sheet lamination method. This method involves forming a via hole in a green sheet obtained by forming slurry of a ceramic powder and an organic binder, screen-printing a conductive paste, overlapping the green sheets in a required number of layers, heating and pressing the green sheets, and then laminating and sintering the green sheets. The green sheet lamination method has the advantages of enabling fine pattern printing because the green sheets are highly flexible and easily absorb organic solvents and of excellent surface smoothness and tightness required for multi-layering up to several tens of layers.

On the other hand, as a disadvantage, in order to obtain a multilayer ceramic substrate, green sheets on which line conductors are formed should be laminated and a sintering process should be performed to obtain excellent characteristics. However, when the sintering process is performed, contraction due to the sintering of the ceramic occurs. It is difficult for this contraction to occur uniformly across the entire multilayer ceramic substrate, resulting in dimensional deformation in a plane direction of a ceramic layer. In addition, the contraction in the plane direction causes undesired deformation or distortion in the line conductor, and more specifically, the positional accuracy of external electrodes for connection of chip components mounted on the multilayer ceramic substrate may be reduced or an open circuit may occur in the line conductor. In this way, when the contraction in the plane direction occurs, misalignment occurs between the conductive pattern and the components when the components are mounted, and thus it is impossible to mount semiconductor chips such as a chip size package (CSP) and multi-chip modules (MCMs) with high precision.

Meanwhile, FIG. 1 shows 2.5D packaging using the conventional single-layer interposer. A fine line width/spacing of 10 μm or less should be implemented on a surface of a ceramic substrate for the interposer, and to this end, a plating process should be applied.

However, when a multilayer ceramic substrate is used as an interposer, the surface of the multilayer ceramic substrate, i.e., a surface of alumina (Al2O3), which is a crystalline ceramic, is very rough due to voids existing therein, and thus there is a limit to implementing a fine line width/line spacing through the plating process.

In addition, although the conventional through glass via (TGV) can implement a fine line width/line spacing of 10 μm or less, there is a limit to forming multiple layers, and the conventional through silicon via (TSV) has the problem of excessive process costs due to the application of semiconductor processes. In addition, a conventional embedded multi-die interconnect bridge (EMIB) has a silicon interposer that connects heterogeneous dies embedded in a flip chip ball grid array (FC-BGA) substrate, but has the disadvantage of limiting a routing length.

### RELATED ART DOCUMENT

### Patent Document

(Patent Document 0001) Korean Patent Registration No. 10-0673860 (Jan. 25, 2007)

### SUMMARY OF THE INVENTION

The present invention is directed to providing a multilayer ceramic substrate having a glass layer formed on one surface of the multilayer ceramic substrate for an interposer manufactured by bonding a plurality of pre-sintered ceramic sheets to implement a fine line width, and a method of manufacturing the same.

According to an aspect of the present invention, there is provided a method of manufacturing a multilayer ceramic substrate having a glass layer, which includes a preparing operation of preparing a plurality of ceramic sheets formed by sintering a ceramic green sheet, a via hole forming operation of forming via holes in the plurality of ceramic sheets, a via electrode forming operation of forming via electrodes in the via holes, a pattern electrode forming operation of forming a pattern electrode on one surface of each of the ceramic sheets, a bonding layer forming operation of applying a bonding agent onto one surface of each of the ceramic sheets to form a bonding layer, a bonding operation of manufacturing a multilayer ceramic substrate by bonding the plurality of the ceramic sheets to each other through the bonding layer, and a glass layer forming operation of forming a glass layer on one side of the manufactured multilayer ceramic substrate to implement a fine line width.

In addition, the glass layer may be formed on each of upper and lower surfaces of the manufactured multilayer ceramic substrate.

In addition, a plating pattern of a preset shape may be formed on an upper surface of the glass layer, a line width of the plating pattern may be 10 μm or less, and a line spacing of the plating pattern may be 10 μm or less.

In addition, in the glass layer forming operation, the bonding layer may be formed by applying the bonding agent onto one surface of the multilayer ceramic substrate, and then the glass layer may be formed by bonding the glass substrate and the multilayer ceramic substrate to each other through the bonding layer.

In addition, in the glass layer forming operation, the glass layer may be formed by forming a bonding glass on one surface of the manufactured multilayer ceramic substrate.

In addition, in the glass layer forming operation, the glass layer may be formed by depositing a glass film on one surface of the manufactured multilayer ceramic substrate.

According to another aspect of the present invention, there is provided a multilayer ceramic substrate, which has a glass layer and is formed by sintering a plurality of ceramic green sheets to form a plurality of ceramic sheets and then laminating the plurality of ceramic sheets, which includes a plurality of ceramic sheets in which via electrodes are formed, a pattern electrode formed on one surface of each of the ceramic sheets, and a bonding layer configured to bond the plurality of ceramic sheets to each other, wherein the glass layer is formed on one surface of the multilayer ceramic substrate to implement a fine line width.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram illustrating 2.5D packaging using a conventional interposer;

FIG. 2 is a flowchart illustrating a method of manufacturing a multilayer ceramic substrate having a glass layer according to one embodiment of the present invention;

FIG. 3 is a diagram illustrating a process of manufacturing the multilayer ceramic substrate according to the method of manufacturing a multilayer ceramic substrate having a glass layer according to one embodiment of the present invention;

FIG. 4 is a diagram illustrating a glass substrate bonded to one surface of the multilayer ceramic substrate manufactured according to the method of manufacturing a multilayer ceramic substrate having a glass layer according to one embodiment of the present invention;

FIG. 5 is a diagram illustrating a bonding glass formed on one surface of the multilayer ceramic substrate manufactured according to the method of manufacturing a multilayer ceramic substrate having a glass layer according to one embodiment of the present invention; and

FIG. 6 is a diagram illustrating a glass material deposited on one surface of the multilayer ceramic substrate manufactured according to the method of manufacturing a multilayer ceramic substrate having a glass layer according to one embodiment of the present invention.

### DETAILED DESCRIPTION OF EXEMPLARY EMBODIMENTS

Hereinafter, some embodiments of the present invention will be described in detail with reference to the illustrative drawings. In giving reference numerals to components of the drawings, the same reference numerals are given to the same components even when the same components are shown in different drawings.

In addition, in describing embodiments of the present invention, when detailed description of related known configurations or functions is determined to hinder understanding of the embodiment of the present invention, the detailed description thereof will be omitted.

Further, in describing components of the embodiment of the present disclosure, terms such as “first,” “second,” “A,” “B,” “(a),” “(b),” etc., can be used. These terms are intended to distinguish one component from other components, but the nature and the order or sequence of the components is not limited by those terms.

Hereinafter, a method S100 of manufacturing a multilayer ceramic substrate having a glass layer according to one embodiment of the present invention will be described in detail with reference to the accompanying drawings.

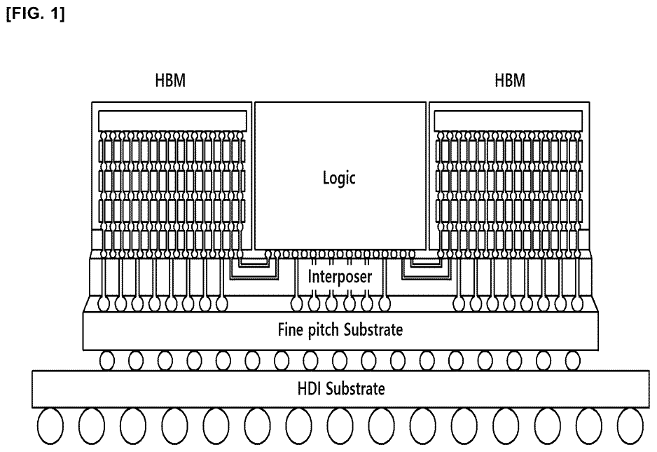

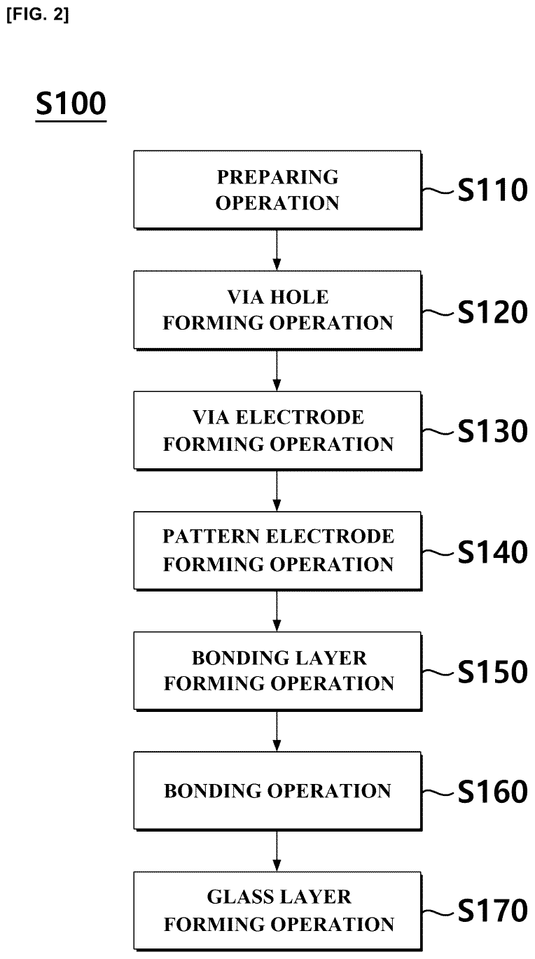

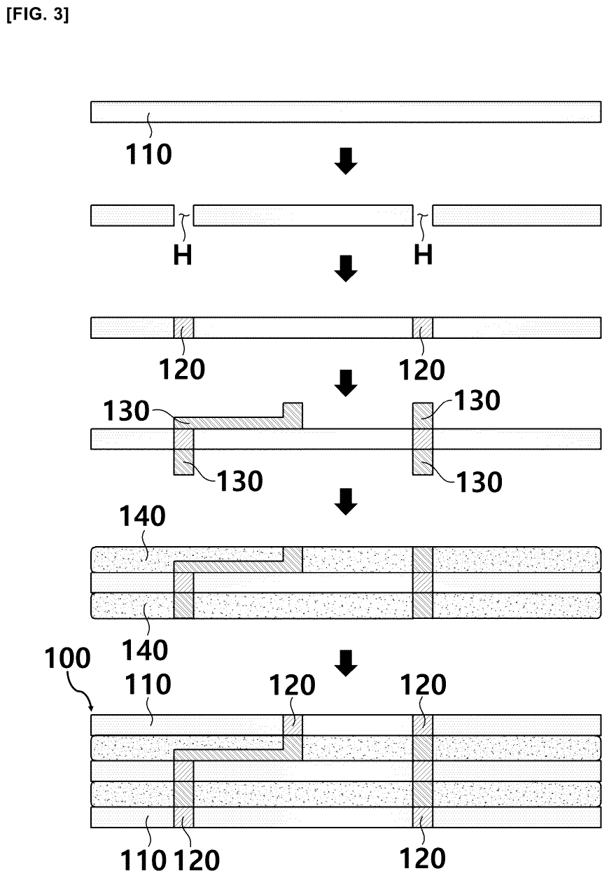

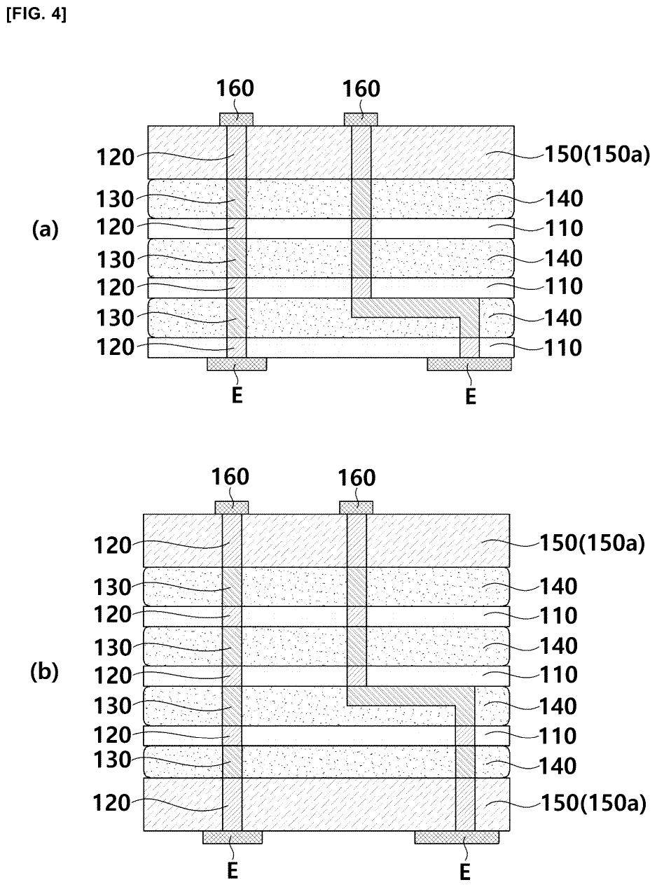

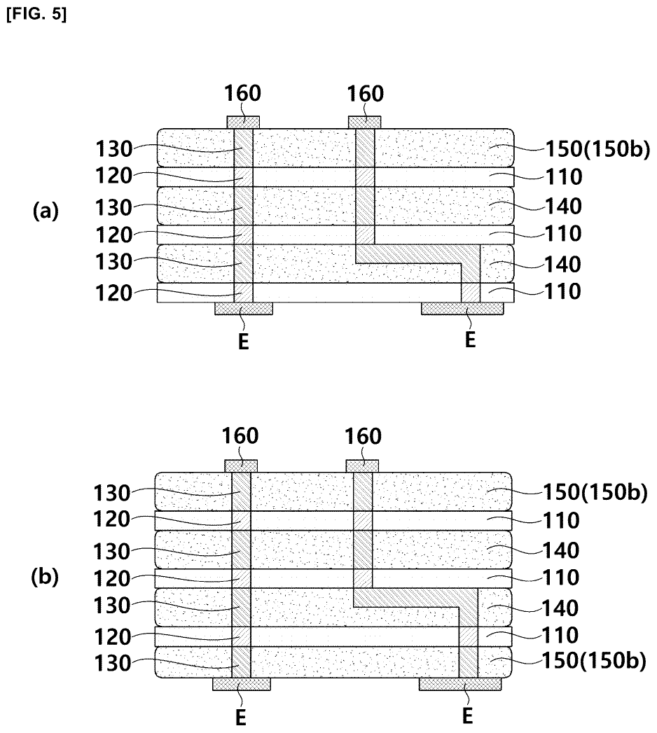

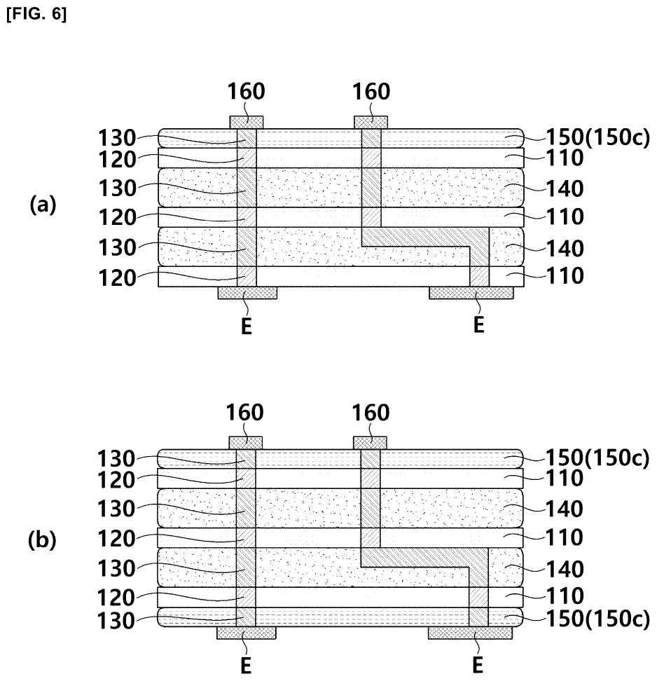

FIG. 1 is a diagram illustrating 2.5D packaging using a conventional interposer, FIG. 2 is a flowchart illustrating a method of manufacturing a multilayer ceramic substrate having a glass layer according to one embodiment of the present invention, FIG. 3 is a diagram illustrating a process of manufacturing the multilayer ceramic substrate according to the method of manufacturing a multilayer ceramic substrate having a glass layer according to one embodiment of the present invention, FIG. 4 is a diagram illustrating a glass substrate bonded to one surface of the multilayer ceramic substrate manufactured according to the method of manufacturing a multilayer ceramic substrate having a glass layer according to one embodiment of the present invention, FIG. 5 is a diagram illustrating a bonding glass formed on one surface of the multilayer ceramic substrate manufactured according to the method of manufacturing a multilayer ceramic substrate having a glass layer according to one embodiment of the present invention, and FIG. 6 is a diagram illustrating a glass material deposited on one surface of the multilayer ceramic substrate manufactured according to the method of manufacturing a multilayer ceramic substrate having a glass layer according to one embodiment of the present invention.

As shown in FIGS. 2 and 3, a method S100 of manufacturing a multilayer ceramic substrate having a glass layer according to one embodiment of the present invention includes a preparing operation S110, a via hole forming operation S120, a via electrode forming operation S130, a pattern electrode forming operation S140, a bonding layer forming operation S150, a bonding operation S160, and a glass layer forming operation S170.

The preparing operation S110 is an operation of preparing a plurality of ceramic sheets 110 formed by sintering a plurality of ceramic green sheets.

A multilayer ceramic substrate 100 having a glass layer 150 according to the present invention is characterized in that, rather than conventionally manufacturing the multilayer ceramic substrate 100 by laminating and then sintering the plurality of ceramic green sheets, the multilayer ceramic substrate 100 is manufactured by sintering the plurality of ceramic green sheets individually to manufacture the plurality of ceramic sheets 110, and then laminating and bonding the manufactured ceramic sheets 110 in order.

A temperature for sintering the ceramic green sheets to manufacture the ceramic sheet 110 in the preparing operation S110 may range from 1000° C. to 1500° C., and the ceramic green sheets may be sintered for 1 hour to 5 hours in an oxygen-free reduction environment or an air environment. In addition, a diameter of the ceramic green sheet and/or the ceramic sheet 110 may be 12 inches or greater, and the ceramic sheet 110 manufactured by sintering the ceramic green sheets may have a thickness of 50 μm to 300 μm.

The via hole forming operation S120 is an operation of forming one or more via holes H in each of the plurality of ceramic sheets 110.

In this case, the via hole H may be formed through a process such as laser radiation or chemical etching, and the via hole H may have a diameter of 50 μm to 300 μm. Meanwhile, the via holes H formed in the same ceramic sheet 110 may have the same diameter or different diameters.

The via electrode forming operation S130 is an operation of forming a via electrode 120 in the via hole H.

More specifically, the via electrode forming operation S130 is an operation of filling and sintering a conductive paste in the via hole H formed in each of the plurality of ceramic sheets 110 to form the via electrode 120. The via electrode 120 serves as an electrode that electrically connects layers when the plurality of ceramic sheets 110 are laminated to manufacture the multilayer ceramic substrate 100. In addition, the conductive paste filling the via hole H may include one or more materials among Ag, Cu, Au, Pd, Pt, Ag-Pd, Ni, Mo, and W, but the present invention is not limited thereto.

The pattern electrode forming operation S140 is an operation of forming a pattern electrode 130 to electrically connect a plurality of via electrodes 120 to each other on one surface of each of the plurality of ceramic sheets 110.

More specifically, the pattern electrode forming operation S140 may form the pattern electrodes 130 by printing a pattern using a conductive paste on one surface of the ceramic sheet 110 other than the ceramic sheet 110 located at the uppermost or lowermost layer of the multilayer ceramic substrate 100 according to the present invention and sintering the pattern. The pattern electrodes 130 are then present inside the multilayer ceramic substrate 100 and may electrically connect the plurality of via electrodes 120 to each other.

In addition, the conductive paste for forming the pattern electrode 130 may include one or more materials among Ag, Cu, Au, Pd, Pt, Ag-Pd, Ni, Mo, and W, but the present invention is not limited thereto.

Meanwhile, a melting point of the pattern electrode 130 may vary depending on a constituent material of the conductive paste for forming the pattern electrode 130. In order to prevent the via electrode 120 formed on the ceramic sheet 110 from melting together with the pattern electrode 130 while sintering in the pattern electrode forming operation S140, the melting point of the pattern electrode 130 (i.e., the melting point of the conductive paste used for the pattern electrode 130) may be set to be lower than the melting point of the ceramic sheet 110 and the melting point of the via electrode 120. Preferably, the pattern electrode forming operation S140 may be sintered at a temperature that is higher than the melting point of the pattern electrode 130 and is lower than the melting point of the via electrode 120.

The bonding layer forming operation S150 is an operation of forming a bonding layer 140 by applying a bonding agent to one surface of each of the plurality of ceramic sheets 110.

More specifically, in the bonding layer forming operation S150, the bonding layer 140 is formed by applying a bonding agent to one surface of the ceramic sheet 110 undergoing the above-described processes to bond the plurality of ceramic sheets 110 to each other. The bonding agent may be prepared as a material that does not affect the printed pattern electrode 130, the bonding agent may be an inorganic and/or organic material, when the bonding agent is an inorganic material, the bonding agent may include glass, ceramic, etc., and when the bonding agent is an organic material, the bonding agent may include epoxy and the like, but the present invention is not limited thereto. Meanwhile, a thickness of the bonding layer 140 may range from 2 μm to 100 μm.

In addition, the melting point of the bonding agent may vary depending on a material constituting the bonding agent. In order to prevent the via electrode 120 and/or the pattern electrode 130 formed on the ceramic sheet 110 from being melted together while sintering in the bonding operation S160, which will be described below, the melting point of the bonding agent may be set to be lower than the melting point of the ceramic sheet 110, the melting point of the via electrode 120, and/or the melting point of the pattern electrode 130.

The bonding operation S160 is an operation of manufacturing the multilayer ceramic substrate 100 by bonding the plurality of ceramic sheets 110 to each other through the bonding layer 140.

More specifically, in the bonding operation S160, the plurality of ceramic sheets 110, on which the bonding agent is applied to form the bonding layer 140, are laminated to manufacture a laminate, the laminate is then sintered to melt the bonding layer 140, and then the bonding layer 140 is cooled again to firmly bond the plurality of ceramic sheets 110 so that the multilayer ceramic substrate 100 in which the plurality of ceramic sheets 110 are bonded to each other may be manufactured.

Accordingly, the via electrodes 120 formed in the ceramic sheets 110 are electrically connected through the pattern electrodes 130 so that the plurality of laminated ceramic sheets 110 may be electrically connected to each other.

Meanwhile, the bonding operation S160 may be sintered at a temperature that is higher than the melting point of the bonding agent and is lower than the melting point of the pattern electrode 130, and the sintering temperature may be set to gradually decrease in the order of the via electrode forming operation S130, the pattern electrode forming operation S140, and the bonding operation S160. Furthermore, the melting point may be set to gradually decrease in the order of the conductive paste used for the via electrode 120, the conductive paste used for the pattern electrode 130, and the bonding agent.

Accordingly, the multilayer ceramic substrate 100 is sintered or heat-treated at a temperature that does not affect the ceramic sheet 110 so that defects such as deformation and cracks occurring in the ceramic sheet 110 itself may be prevented.

The glass layer forming operation S170 is an operation of forming a glass layer 150 to implement a fine line width on one side of the multilayer ceramic substrate 100 manufactured through the bonding operation S160.

A fine line width/spacing of 10 μm or less should be implemented on the surface of the multilayer ceramic substrate 100 for the interposer, and to this end, a plating process should be applied. However, since the surface of the multilayer ceramic substrate 100, i.e., a surface of alumina (Al2O3), which is a crystalline ceramic, is very rough due to voids existing inside, there is a limit to implementing a fine line width/line spacing through the plating process. In addition, although TGV may implement a fine line width/line spacing of 10 μm or less, there is a limit to forming multiple layers. Accordingly, in the present invention, the glass layer 150 having a mirrored surface is formed on one surface of the multilayer ceramic substrate 100 so that a surface of the multilayer ceramic substrate 100 for the interposer allows a plating process to be performed thereon.

In this case, as shown in FIG. 4, in the glass layer forming operation S170 of the present invention, a bonding agent is applied to one surface of the multilayer ceramic substrate 100 to form the bonding layer 140, and then a glass substrate 150a and the multilayer ceramic substrate 100 are bonded to each other through the bonding layer 140 so that the glass layer 150 may be formed.

Here, the glass substrate 150a may be formed in a predetermined substrate shape by melting, molding, cooling, and then annealing a glass composition and may be formed as a plate glass such as, for example, a soda lime silicate substrate. A glass transition temperature (Tg) of the glass substrate 150a may be a bonding temperature or higher, and the via hole H may be formed inside the glass substrate 150a in the same manner as the ceramic sheet 110, and then the via electrode 120 may be formed.

In addition, the bonding agent may be an inorganic and/or organic material, when the bonding agent is an inorganic material, the bonding agent may include glass, ceramic, etc., and when the bonding agent is an organic material, the bonding agent may include epoxy, etc., but the present invention is not limited thereto. Meanwhile, a thickness of the glass substrate 150 a may range from 50 μm to 300 μm, and a thickness of the bonding layer 140 may range from 2 μm to 100 μm.

In addition, as shown in FIG. 5, in the glass layer forming operation S170 of the present invention, the glass layer 150 may be formed by applying a bonding glass 150b onto one surface of the manufactured multilayer ceramic substrate 100.

Here, the bonding glass 150b may be an inorganic and/or organic material, when the bonding glass 150b is an inorganic material, the bonding glass 150b may include glass (a glass film), ceramic, etc., and when the bonding glass 150b is an organic material, the bonding glass 150b may include epoxy, etc., but the present invention is not limited thereto. Meanwhile, a thickness of the bonding glass 150b may range from 2 μm to 100 μm.

In addition, as shown in FIG. 6, in the glass layer forming operation S170 of the present invention, an amorphous dielectric thin film glass layer 150 may be formed by forming a glass film 150c on one surface of the manufactured multilayer ceramic substrate 100.

Here, when a material constituting the glass film 150c is an inorganic material, the glass film 150c may include glass (a glass film), ceramic, etc., and when a material constituting the glass film 150c is an organic material, the glass film 150c may include epoxy, etc. Meanwhile, a thickness of the glass film 150c may range from 1 μm to 100 μm, and known coating or deposition techniques such as physical vapor deposition (PVD) such as sol-gel coating and sputtering, or chemical vapor deposition (CVD) such as metal organic CVD (MOCVD) may be used.

Meanwhile, as shown in FIGS. 4A, 5A, and 6A, the glass layer 150 may be formed only on an upper surface of the manufactured multilayer ceramic substrate 100, and preferably, as shown in FIGS. 4B, 5B, and 6B, in order to prevent thermal deformation such as bowing from occurring due to a difference in coefficient of thermal expansion (CTE) between the glass layer 150 and the multilayer ceramic substrate 100, the glass layer 150 may be formed on upper and lower surfaces of the multilayer ceramic substrate 100. In addition, after the glass layer 150 is formed on one surface of the multilayer ceramic substrate 100, the surface of the glass layer 150 may be mirrored smoothly through polishing, etc.

In addition, after the glass layer forming operation S170, a plating process may be performed on the upper surface of the glass layer 150.

That is, a fine plating pattern 160 having a preset shape may be formed on the upper surface of the mirrored glass layer 150. A line width of the formed fine plating pattern may be 10 μm or less, and a line spacing may be 10 μm or less. Preferably, the line width of the fine plating pattern may be 5 μm or less, and the line spacing may be 5 μm or less.

Furthermore, after the glass layer forming operation S170, an external electrode E or a pad electrode may be formed on the upper surface of the glass layer 150 or the ceramic sheet 110 (when the glass layer 150 is not formed). Finally, the external electrode E formed in the lowermost layer may be electrically connected to the pattern electrode 130 of each layer and the fine plating pattern 160 formed in the uppermost layer through the via electrode 120.

The multilayer ceramic substrate 100 having the glass layer 150 manufactured after undergoing the above-described operations includes the plurality of ceramic sheets 110 on which at least one via electrode 120 is formed, the pattern electrode formed on one surface of the ceramic sheets 110 to electrically connect the plurality of via electrodes 120 to each other, and the bonding layer 140 for bonding the plurality of ceramic sheets 110 to each other, the glass layer 150 for implementing a fine line width is formed on one surface of the multilayer ceramic substrate 100, and the glass layer 150 may be formed by bonding the glass substrate 150a through the bonding layer 140, forming the bonding glass 150b, or depositing the glass film 150c.

According to the present invention, there is an effect that a fine line width/spacing of 5 μm or less can be implemented on a surface of a multilayer ceramic substrate for an interposer through a mirrored glass layer.

In addition, according to the present invention, since a ceramic substrate for the interposer has a multilayer structure and a circuit is formed in an inner layer, there is an advantage of easy impedance matching compared to a through glass via (TGV) of the conventional single-layer, and there is an advantage of lower process cost and no limitation on a routing length compared to the conventional through silicon via (TSV) and embedded multi-die interconnect bridge (EMIB).

Meanwhile, the effects of the present invention are not limited to the effects mentioned above, and various effects may be included within a range obvious to those skilled in the art from the content which will be described below.

Although all components constituting embodiments of the present invention have been described above as being combined as one or operating in combination, the present invention is not necessarily limited to these embodiments. That is, within the scope of the present invention, one or more of all the components may be selectively combined and operated.

In addition, the terms “include,” “constitute,” and “have” as described above imply that the corresponding component may be present unless otherwise specifically stated, and therefore it should be construed that other components may be further included rather than being excluded. Unless otherwise defined, all terms including technical or scientific terms have the same meaning as commonly understood by those skilled in the art to which the present invention pertains. Commonly used terms, such as terms defined in the dictionary, should be construed as consistent with their contextual meaning in the relevant art and will not be interpreted as having an idealistic or excessively formalistic meaning unless clearly defined in the present specification.

In addition, although the embodiments have been described with reference to a number of illustrative embodiments of the technical spirit of the present invention, it should be understood that numerous other modifications and embodiments can be devised by those skilled in the art that will fall within the spirit and scope of the principles of the present invention.

The embodiments disclosed herein, therefore, are not to be taken in a sense for limiting the technical spirit of the present invention but for explanation thereof, and the range of the technical spirit of the present invention is not limited to these embodiments. The scope of the present invention should be construed based on the appended claims, along with the full range of equivalents to which such claims are entitled.

What is claimed is:

1. A method of manufacturing a multilayer ceramic substrate having a glass layer, the method comprising:
a preparing operation of preparing a plurality of ceramic sheets formed by sintering ceramic green sheets;
a via hole forming operation of forming via holes in the plurality of ceramic sheets;
a via electrode forming operation of forming via electrodes in the via holes;
a pattern electrode forming operation of forming a pattern electrode on one surface of each of the ceramic sheets;
a bonding layer forming operation of applying a bonding agent onto one surface of each of the ceramic sheets to form a bonding layer;
a bonding operation of manufacturing a multilayer ceramic substrate by bonding the plurality of ceramic sheets to each other through the bonding layer; and
a glass layer forming operation of forming a glass layer on one side of the manufactured multilayer ceramic substrate to implement a fine line width.

2. The method of claim 1, wherein the glass layer is formed on each of upper and lower surfaces of the manufactured multilayer ceramic substrate.

3. The method of claim 1, wherein:
a plating pattern of a preset shape is formed on an upper surface of the glass layer;
a line width of the plating pattern is 10 μm or less; and
a line spacing of the plating pattern is 10 μm or less.

4. The method of claim 3, wherein, in the glass layer forming operation, the bonding layer is formed by applying the bonding agent onto one surface of the multilayer ceramic substrate, and then the glass layer is formed by bonding the glass substrate and the multilayer ceramic substrate to each other through the bonding layer.

5. The method of claim 3, wherein, in the glass layer forming operation, the glass layer is formed by forming a bonding glass on one surface of the manufactured multilayer ceramic substrate.

6. The method of claim 3, wherein, in the glass layer forming operation, the glass layer is formed by depositing a glass film on one surface of the manufactured multilayer ceramic substrate.

7. A multilayer ceramic substrate which has a glass layer and is formed by sintering a plurality of ceramic green sheets to form a plurality of ceramic sheets and then laminating the plurality of ceramic sheets, the multilayer ceramic substrate comprising:
a plurality of ceramic sheets in which via electrodes are formed;
a pattern electrode formed on one surface of each of the ceramic sheets; and
a bonding layer configured to bond the plurality of ceramic sheets to each other,
wherein the glass layer is formed on one surface of the multilayer ceramic substrate to implement a fine line width.
